(19) United States
(12) Patent Application Publication
(10) Pub. No.: US 2025/0301824 A1
(43) Pub. Date: Sep. 25, 2025

(54) METHOD OF MEASURING MICRO LED ELECTROLUMINESCENCE (EL) BY USING PHOTOELECTRIC EFFECT

(71) Applicants: INDUSTRY ACADEMIC COOPERATION FOUNDATION OF YEUNGNAM UNIVERSITY, Gyeongsan-si (KR); ULTECH CO., LTD., Daegu (KR)

(72) Inventors: Si-Hyun PARK, Daegu (KR); Huijin KIM, Daegu (KR); Young-Woong LEE, Daegu (KR); Boseong SON, Daegu (KR)

(73) Assignees: INDUSTRY ACADEMIC COOPERATION FOUNDATION OF YEUNGNAM UNIVERSITY, Gyeongsan-si (KR); ULTECH CO., LTD., Daegu (KR)

(21) Appl. No.: 19/036,990

(22) Filed: Jan. 24, 2025

(30) Foreign Application Priority Data
Mar. 20, 2024 (KR) 10-2024-0038239

(51) Int. Cl. H10H 20/01; G01R 31/26; H01L 21/66

(52) U.S. Cl. CPC H10H 20/017; G01R 31/2635; H01L 22/10

(57) ABSTRACT

Proposed is a method of measuring micro LED electroluminescence by using a photoelectric effect, having the following effects: a micro LED epitaxy wafer and a micro LED verification substrate are included and allowed to be connected to each other in parallel when the micro LED epitaxy wafer and the micro LED verification substrate come into contact; electric power is indirectly applied by using the photoelectric effect, so as to enable measurement of the electroluminescence (EL) at high speed; a way of applying voltage by using the photoelectric effect requires photon energy to be smaller than a bandgap of a target LED material and to be larger than bandgap energy of a material for the micro LED verification substrate; and the micro LED verification substrate is composed of a material for generating the photoelectric effect, so as to enable maximally increasing the effectiveness of the electroluminescence measurement using the photoelectric effect.

### CROSS REFERENCE TO RELATED APPLICATION

The present application claims priority to Korean Patent Application No. 10-2024-0038239, filed Mar. 20, 2024, the entire contents of which are incorporated herein for all purposes by this reference.

### BACKGROUND OF THE INVENTION

### Field of the Invention

The present disclosure relates to a technology regarding a method of measuring micro LED electroluminescence (EL) by using a photoelectric effect, the method having the following characteristics: a micro LED epitaxy wafer and a micro LED verification substrate are included and allowed to be connected to each other in parallel when the micro LED epitaxy wafer and the micro LED verification substrate come into contact; electric power is indirectly applied by using the photoelectric effect, so as to enable measurement of the electroluminescence (EL) at high speed; a way of applying voltage by using the photoelectric effect requires photon energy to be smaller than a bandgap of a target LED material and to be larger than bandgap energy of a material for the micro LED verification substrate; the micro LED verification substrate is composed of a material for generating the photoelectric effect, so as to enable maximally increasing the effectiveness of the electroluminescence (EL) measurement using the photoelectric effect; the micro LED epitaxy wafer is same as an existing micro LED epitaxy wafer, but is allowed to have an arrangement for matching the micro LED epitaxy wafer and the micro LED verification substrate, so as to enable maximally increasing the effectiveness of light emission; and a layer of the micro LED verification substrate is simplified, so as to enable measurement of more chips at high speed than the electroluminescence (EL) measurement using a conventional method of injecting direct current.

### Description of the Related Art

Micro LEDs are ultra-small LEDs that are tens of microns in size, and when used as elements in displays, they have advantages of higher power efficiency, shorter response time, higher brightness, and longer service spans compared to conventional displays, thereby emerging as a core technology for next-generation displays that will replace OLED and LCD.

The micro LED market is first formed starting from year 2017, and is expected to form a large-scale market worth 4.5 to 20 billion dollars by year 2025 through its growth at an average annual rate of 70%, thereby leading to fierce competition among companies in order to secure market and technological superiority.

Currently, display panels applied with micro LEDs are being developed for commercialization by various groups including Samsung Electronics and LG Electronics in South Korea and PlayNitride, Apple, etc. overseas. However, due to each micro LED in a smaller size, developing new process technologies and equipment that are completely different from the existing LED industry is required from a production process to inspection and evaluation processes, and due to each micro LED in the smaller size, introducing the new process technologies that are completely different from the existing LED industry is also required from the production process to the inspection, evaluation, and repair processes.

The pixels of a micro LED display panel require securing uniformity in a stricter standard than that of the optical quality of LEDs used for general lighting.

Accordingly, a stabilized process line is required to prevent the occurrence of a defective pixel by applying the strict standard during a manufacturing process stage, and a process and equipment for repairing micro LEDs at a position where the defective pixel occurs are also essential.

In this case, it is important to inspect and verify micro LEDs transferred onto an arbitrary substrate so as not to create a re-defect rate after the repair process. In the process of repairing defective pixels in displays applied with a general LED PKG, repair is allowed to proceed in a case of 10 or fewer defective pixels, but in a case of exceeding 10 defective pixels, a corresponding panel is determined as defective and discarded.

A current repair process does not measure the characteristics of LEDs separately, but rather applies each LED PKG provided by a manufacturer as is, and after completing such a repair process, whether each LED PKG used is defective or not can be determined. At this time, in a case where a defect occurs again, the repair process in which a corresponding LED PKG is removed and newly attached again is repeatedly performed.

As described above, when the repair process is performed again, a problem of a panel copper plate falling off occurs, so a corresponding panel is treated as defective and should be discarded, thereby causing a problem of time and cost. Meanwhile, in a case of a display panel applied with micro LEDs, the repair process of small pixel control, selective transfer, bonding, etc. is complex and difficult. Since it is difficult to perform the repair again, the repair should be performed by using micro LED chips having verified characteristics.

However, electroluminescence (EL) inspection equipment is difficult to apply to mass production because not only scratches or cracks are formed on p and n electrodes during probing due to too small micro LED chips but also high-speed probing is difficult to perform, and thus there is actually a need to develop electroluminescence (EL) inspection equipment applicable to the mass production.

Meanwhile, there is no development yet for a method of measuring micro LED electroluminescence (EL) by using a photoelectric effect, the method having the following characteristics: a micro LED epitaxy wafer is same as an existing micro LED epitaxy wafer, but is allowed to have an arrangement for matching the micro LED epitaxy wafer and a micro LED verification substrate, so as to enable maximally increasing the effectiveness of light emission; and a layer of the micro LED verification substrate is simplified, so as to enable measurement of more chips at high speed than the electroluminescence (EL) measurement using a conventional method of injecting direct current.

Therefore, there is an urgent need to develop a method of measuring micro LED electroluminescence (EL) by using a photoelectric effect, the method having the following characteristics: a micro LED epitaxy wafer and a micro LED verification substrate are included and allowed to be connected to each other in parallel when the micro LED epitaxy wafer and the micro LED verification substrate come into contact; electric power is indirectly applied by using the photoelectric effect, so as to enable measurement of the electroluminescence (EL) at high speed; a way of applying voltage by using the photoelectric effect requires photon energy to be smaller than a bandgap of a target LED material and to be larger than bandgap energy of a material for the micro LED verification substrate; the micro LED verification substrate is composed of a material for generating the photoelectric effect, so as to enable maximally increasing the effectiveness of the electroluminescence (EL) measurement using the photoelectric effect; the micro LED epitaxy wafer is same as an existing micro LED epitaxy wafer, but is allowed to have an arrangement for matching the micro LED epitaxy wafer and the micro LED verification substrate, so as to enable maximally increasing the effectiveness of light emission; and a layer of the micro LED verification substrate is simplified, so as to enable measurement of more chips at high speed than the electroluminescence (EL) measurement using a conventional method of injecting direct current.

### Documents of Related Art

(Patent Document 1) KR 10-2008-0111962 (Dec. 24, 2008)

### SUMMARY OF THE INVENTION

Accordingly, the present disclosure has been devised to solve the above problems, and an objective of the present disclosure is to provide a method of measuring micro LED electroluminescence (EL) by using a photoelectric effect, that is, a micro LED electroluminescence (EL) measurement method wherein a micro LED epitaxy wafer and a micro LED verification substrate are included and allowed, when the micro LED epitaxy wafer and the micro LED verification substrate come into contact, to be connected to each other in parallel, and electric power is indirectly applied by using the photoelectric effect, so as to enable measurement of the electroluminescence (EL) at high speed.

In addition, another objective of the present disclosure is to provide a method of measuring micro LED electroluminescence (EL) by using a photoelectric effect, that is, a micro LED electroluminescence (EL) measurement method wherein a way of applying voltage by using the photoelectric effect requires photon energy to be smaller than a bandgap of a target LED material and to be larger than bandgap energy of a material for the micro LED verification substrate, and the micro LED verification substrate is composed of a material for generating the photoelectric effect, so as to enable maximally increasing the effectiveness of the electroluminescence (EL) measurement using the photoelectric effect.

In addition, a yet another objective of the present disclosure is to provide a method of measuring micro LED electroluminescence (EL) by using the photoelectric effect, that is, a micro LED electroluminescence (EL) measurement method wherein the micro LED epitaxy wafer is same as an existing micro LED epitaxy wafer, but is allowed to have an arrangement for matching the micro LED epitaxy wafer and the micro LED verification substrate, so as to enable maximally increasing the effectiveness of light emission.

In addition, a still another objective of the present disclosure is to provide a method of measuring micro LED electroluminescence (EL) by using the photoelectric effect, that is, a micro LED electroluminescence (EL) measurement method wherein a layer of the micro LED verification substrate is simplified, so as to enable measurement of more chips at high speed than the electroluminescence (EL) measurement using a conventional method of injecting direct current.

According to a preferred exemplary embodiment of the present disclosure to achieve the above objectives, there is provided a method of measuring micro LED electroluminescence (EL) by using a photoelectric effect, the method including: step (a) of manufacturing a micro LED verification substrate in a form of a pn junction composed of a material for generating the photoelectric effect; step (b) of aligning and contacting each micro LED chip on the micro LED epitaxy wafer with the corresponding electrode pad on the micro LED verification substrate so that they match in a one-to-one correspondence; and step (c) of generating photoluminescence with current flowing through the micro LED epitaxy wafer when voltage is induced by emitting light to the micro LED verification substrate.

In the present disclosure, step (a) may include allowing a way of etching the pn junction and a way of doping a material having a different polarity to be applicable when the micro LED verification substrate is manufactured.

In the present disclosure, step (a) may include forming a structure in which a plurality of pn junctions is in series connection, so as to enable improving the voltage.

In the present disclosure, step (c) may include simplifying the layer of the micro LED verification substrate and applying a way of injecting indirect current, so as to enable measurement of more chips at high speed than the measurement of electroluminescence (EL) by using a conventional method of injecting direct current.

In the present disclosure, step (c) may include controlling an emission intensity of the light (the laser light), so as to enable controlling an amount of current applied to an LED in the emitting of the light.

In the present disclosure, the method may further include using wide bandgap materials such as GaN, SiC, ZnO, TiO2, and BN, so as to enable improving the voltage because the micro LED electroluminescence (EL) measurement method using the photoelectric effect is not limited to sunlight.

The method of measuring the micro LED electroluminescence (EL) using the photoelectric effect according to the present disclosure exhibits the following effects.

First, in the present disclosure, a micro LED epitaxy wafer and a micro LED verification substrate are included and allowed, when the micro LED epitaxy wafer and the micro LED verification substrate come into contact, to be connected to each other in parallel, and electric power is indirectly applied by using the photoelectric effect, so as to enable measurement of the electroluminescence (EL) at high speed.

Second, in the present disclosure, a way of applying voltage by using the photoelectric effect requires photon energy to be smaller than a bandgap of a target LED material and to be larger than bandgap energy of a material for the micro LED verification substrate, and the micro LED verification substrate is composed of a material for generating the photoelectric effect, so as to enable maximally increasing the effectiveness of the electroluminescence (EL) measurement using the photoelectric effect.

Third, in the present disclosure, the micro LED epitaxy wafer is same as an existing micro LED epitaxy wafer, but is allowed to have an arrangement for matching the micro LED epitaxy wafer and the micro LED verification substrate, so as to enable maximally increasing the effectiveness of light emission.

Fourth, in the present disclosure, a layer of the micro LED verification substrate is simplified, so as to enable measurement of more chips at high speed than the electroluminescence (EL) measurement using a conventional method of injecting direct current.

### BRIEF DESCRIPTION OF THE DRAWINGS

FIG. 1 is a view illustrating a method of manufacturing a micro LED verification substrate according to an exemplary embodiment of the present disclosure.

FIG. 2 is a view illustrating a form in which a micro LED epitaxy wafer is arranged to match a micro LED verification substrate according to the exemplary embodiment of the present disclosure.

FIG. 3 is a view illustrating a form in which light is emitted to the micro LED verification substrate and photoluminescence is generated with current flowing through the micro LED epitaxy wafer according to the exemplary embodiment of the present disclosure.

FIG. 4 is a view illustrating a form of a structure in which a plurality of pn junctions is in series connection when a micro LED verification substrate is manufactured according to the exemplary embodiment of the present disclosure.

FIG. 5 is a flowchart for measuring micro LED electroluminescence (EL) by using a photoelectric effect according to the exemplary embodiment of the present disclosure.

### DETAILED DESCRIPTION OF THE INVENTION

Hereinafter, a preferred exemplary embodiment of the present disclosure will be described as follows with reference to the attached drawings. In describing the present disclosure, in a case where it is determined that a detailed description of a related known technology or configuration may unnecessarily obscure the gist of the present disclosure, the detailed description will be omitted. The terms described below are terms defined in consideration of their functions in the present disclosure, and may vary depending on the intention of a user or operator, custom, or the like, so the definitions should be based on the content throughout the present specification that describes a method of measuring micro LED electroluminescence (EL) by using a photoelectric effect of the present disclosure.

Hereinafter, the method of measuring the micro LED electroluminescence (EL) by using the photoelectric effect according to the preferred exemplary embodiment of the present disclosure is described in detail.

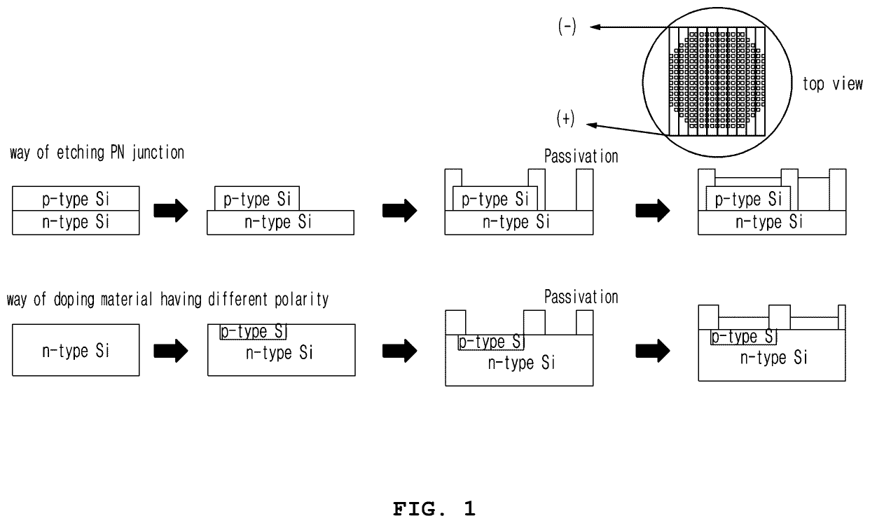

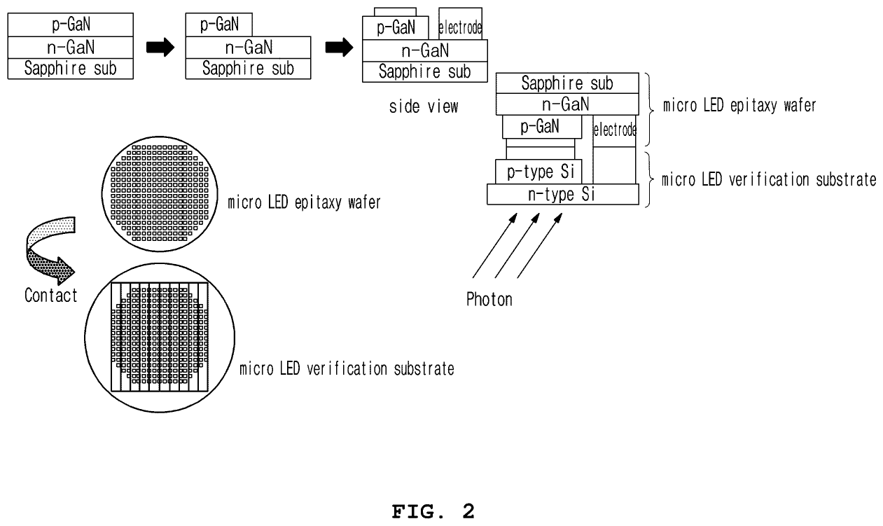

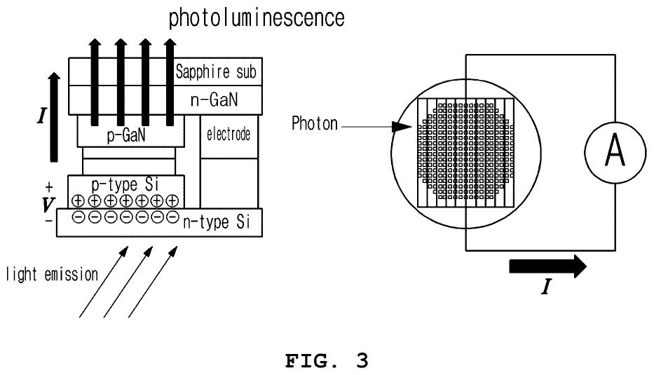

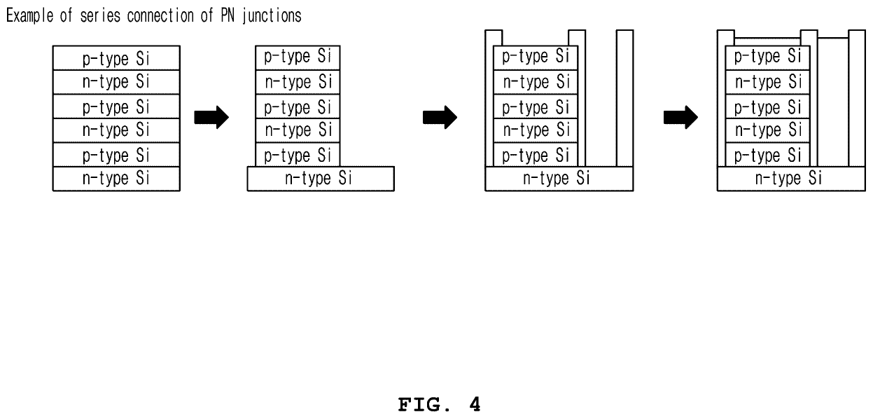

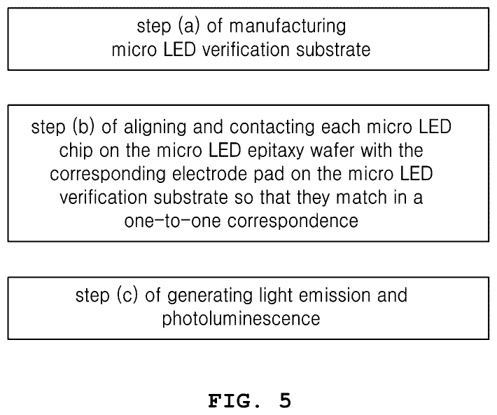

FIG. 1 is a view illustrating a method of manufacturing a micro LED verification substrate according to an exemplary embodiment of the present disclosure. FIG. 2 is a view illustrating a form in which a micro LED epitaxy wafer is arranged to match a micro LED verification substrate according to the exemplary embodiment of the present disclosure. FIG. 3 is a view illustrating a form in which light is emitted to the micro LED verification substrate and photoluminescence is generated with current flowing through the micro LED epitaxy wafer according to the exemplary embodiment of the present disclosure. FIG. 4 is a view illustrating a form of a structure in which a plurality of pn junctions is in series connection when a micro LED verification substrate is manufactured according to the exemplary embodiment of the present disclosure. FIG. 5 is a flowchart for measuring micro LED electroluminescence (EL) by using a photoelectric effect according to the exemplary embodiment of the present disclosure.

As illustrated in FIGS. 1 to 5, the method of measuring the micro LED electroluminescence (EL) by using the photoelectric effect includes: step (a) of manufacturing a micro LED verification substrate in a form of a pn junction composed of a material for generating the photoelectric effect; step (b) of aligning and contacting each micro LED chip on the micro LED epitaxy wafer with the corresponding electrode pad on the micro LED verification substrate so that they match in a one-to-one correspondence; and step (c) of generating photoluminescence with current flowing through the micro LED epitaxy wafer when voltage is induced by emitting light to the micro LED verification substrate.

The functions of the technical steps constituting the method of measuring the micro LED electroluminescence (EL) by using the photoelectric effect are as follows.

First, in step (a) of manufacturing the micro LED verification substrate, the micro LED verification substrate is manufactured in the form of the pn junction composed of the material for generating the photoelectric effect.

Here, as illustrated in FIG. 1, a way of etching a pn junction and a way of doping a material having a different polarity are applicable when the micro LED verification substrate is manufactured.

In addition, in pn junctions, as illustrated in FIG. 4, voltage can be improved by forming a structure in which a plurality of pn junctions is in series connection.

Second, in step (b) of arranging the micro LED epitaxy wafer to match the micro LED verification substrate, as illustrated in FIG. 2, the micro LED epitaxy wafer is arranged to match the micro LED verification substrate.

Third, in step (c) of emitting the light and generating the photoluminescence, as illustrated in FIG. 3, the photoluminescence is generated with the current flowing through the micro LED epitaxy wafer when the voltage is induced by emitting light to the micro LED verification substrate.

Here, the layer of the micro LED verification substrate is simplified and the way of injecting indirect current is applied, so as to enable measurement of more chips at high speed than the measurement of electroluminescence (EL) by using the conventional method of injecting direct current.

In addition, in the emitting of the light, an emission intensity of the light (the laser light) is controlled, so as to enable controlling an amount of current applied to an LED.

As described above, the method of measuring the micro LED electroluminescence (EL) by using the photoelectric effect is not limited to sunlight, and this method uses the photoelectric effect uses wide bandgap materials such as GaN, SiC, ZnO, TiO2, and BN, so as to enable improving the voltage.

In addition, the electroluminescence (EL) is a phenomenon in which light is emitted when an electric field is applied to a material such as a semiconductor.

The electroluminescence is divided into an injection type and an intrinsic type. The injection-type electroluminescence corresponds to a case where electrons and holes are injected by the action of an electric field and light is generated by their recombination, and a light-emitting diode (LED) is a representative example.

In addition, the intrinsic-type electroluminescence is a phenomenon in which electrons accelerated by an electric field collide with a certain luminescent center, causing the luminescent center to become excited and emit light. Examples of the intrinsic-type electroluminescence include electroluminescent cables and electroluminescent thin films.

In addition, luminescent materials are classified into organic materials or inorganic materials, so the former is classified as organic electroluminescence and the latter is classified as inorganic electroluminescence.

As described above, the method of measuring the micro LED electroluminescence (EL) by using the photoelectric effect may be applied to the field of micro LED electroluminescence (EL) measurement, so its application scope is wide.

The best exemplary embodiment is disclosed in the drawings and specification, and the terms used herein are used only for the purpose of describing the present disclosure, and are not used to limit the meaning or the scope of the present disclosure described in the claims. Therefore, those skilled in the art will be able to make various modifications and equivalent other exemplary embodiments from this, and accordingly, the true technical protection scope of the present disclosure should be determined by the technical idea of the appended patent claims.

This invention was supported by the Regional Innovation Strategy (RIS) of the National Research Foundation of Korea (NRF), funded by the Ministry of Education (MOE) (Grant No. 2022RIS-006).

What is claimed is:

1. A method of measuring micro LED electroluminescence (EL) by using a photoelectric effect, the method comprising:
step (a) of manufacturing a micro LED verification substrate in a form of a pn junction composed of a material for generating the photoelectric effect;
step (b) of aligning and contacting each micro LED chip on the micro LED epitaxy wafer with the corresponding electrode pad on the micro LED verification substrate so that they match in a one-to-one correspondence; and
step (c) of generating photoluminescence with current flowing through the micro LED epitaxy wafer when voltage is induced by emitting light to the micro LED verification substrate.

2. The method of claim 1, wherein step (a) comprises allowing a way of etching the pn junction and a way of doping a material having a different polarity to be applicable when the micro LED verification substrate is manufactured.

3. The method of claim 1, wherein step (a) comprises forming a structure in which a plurality of pn junctions is in series connection, so as to enable improving the voltage.

4. The method of claim 1, wherein step (c) comprises simplifying the layer of the micro LED verification substrate and applying a way of injecting indirect current, so as to enable measurement of more chips at high speed than the measurement of electroluminescence (EL) by using a conventional method of injecting direct current.

5. The method of claim 1, wherein step (c) comprises controlling an emission intensity of the light (the laser light), so as to enable controlling an amount of current applied to an LED in the emitting of the light.

6. The method of claim 1, further comprising:
using wide bandgap materials such as GaN, SiC, ZnO, TiO2, and BN, so as to enable improving the voltage because the micro LED electroluminescence (EL) measurement method using the photoelectric effect is not limited to sunlight.
